(19) United States
(12) Patent Application Publication
(10) Pub. No.: US 2008/0127892 A1
(43) Pub. Date: Jun. 5, 2008

(54) Plasma Processing Apparatus with Scanning Injector and Plasma Processing Method

(75) Inventor: Tai Ho Kim, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Incheon-si (KR)

(21) Appl. No.: 11/761,059

(22) Filed: Jun. 11, 2007

(30) Foreign Application Priority Data
Nov. 30, 2006 (KR) 10-2006-0120160

(51) Int. Cl. H01L 21/00; B05C 11/00

(52) U.S. Cl. 118/712; 438/5; 257/E21.002

(57) ABSTRACT

A plasma processing apparatus includes a process chamber having a wafer mounted therein such that a plasma process is performed on the wafer, and an X-axis scanning injector mounted in the process chamber such that the X-axis scanning injector supplies a first local plasma of a reaction gas to a local region on the wafer. The X-axis scanning injector is movable in the X-axis direction to scan the first local plasma over the entire area of the wafer. A Y-axis scanning injector is mounted in the process chamber such that the Y-axis scanning injector supplies a second local plasma of a reaction gas to a local region on the wafer. The Y-axis scanning injector is movable in the Y-axis direction to scan the second local plasma over the entire area of the wafer. The deposition accomplished by the local plasmas over the entire area of the wafer by the X-axis and Y-axis scanning operations.

### CROSS-REFERENCES TO RELATED APPLICATIONS

The present application claims priority to Korean patent application number 10-2006-0120160, filed on Nov. 30, 2006, which is incorporated by reference in its entirety.

### BACKGROUND

This patent relates to the manufacture of a semiconductor device, and, more particularly, to a plasma processing apparatus with a scanning injector.

In general, a plasma process is used when manufacturing an integrated circuit device or a semiconductor device. In the plasma process, plasma is used to deposit or etch a thin layer. The plasma process may be a process for exciting plasma in a process chamber that is isolated from the outside and maintained at a pressure much lower than the atmospheric pressure or under vacuum and depositing a thin layer on a semiconductor substrate or a wafer through the reaction of the plasma or etching the thin layer.

For example, a plasma enhanced-chemical vapor deposition (PE-CVD) apparatus is used in a process for exciting a reaction gas into plasma and depositing an oxide layer or a metal layer on a semiconductor substrate through the reaction of the plasma. Also, a high density plasma chemical vapor deposition apparatus is used to excite plasma and repeatedly perform deposition and etching processes, thereby depositing a relatively high density oxide film. A plasma etching apparatus is used to excite a reaction gas into plasma and etch a thin layer formed on a semiconductor substrate through the reaction of the plasma.

A plasma process using such a plasma processing apparatus may be affected by the structure of a vacuum pump, a radio frequency generating part for generating plasma, and a chamber, or the structure of a gas injector for supplying a reaction gas. The uniformity of a deposition layer may be affected by the gas injector through which gas is injected. The gas injector may be classified as a shower head type gas injector that uses a shower head mounted above a wafer or a straw type gas injector which injects gas through straws mounted around a wafer.

The shower head type gas injector is a direct injection type gas injector. In the shower head type gas injector, the thickness or characteristics of a deposition layer at the center of a wafer may be different from those of the deposition layer at the edge of the wafer. As a result, it is possible to acquire a wafer map having deposition characteristics measured in the shape of an annual ring. Even when a reaction gas is uniformly injected into a process chamber, it is difficult to apply power necessary for generating plasma in the process chamber while uniformly maintaining the density of the power. Consequently, the characteristics or thickness uniformity characteristics of a thin layer may appear in the form of an annual ring-shaped wafer map. For example, a thickness profile may be formed such that the central part of the wafer is thick whereas the edge part of the wafer is thin, or the central part of the wafer is thin whereas the edge part of the wafer is thick. As a result, the yield rate of semiconductor device chips and the operating speed of semiconductor devices may be changed depending upon positions of the wafer.

The straw type gas injector may be constructed in a structure in which a plurality of injection nozzles extend to the top of a wafer from the edge of the wafer. In the straw type gas injector, it is difficult to uniformly control the amount of gas injected from the respective injection nozzles. As a result, it is difficult to improve the uniformity of a thin layer.

### BRIEF SUMMARY OF THE INVENTION

In accordance with the herein described embodiments, a plasma processing apparatus may be capable of performing a plasma process more uniformly over the entire area of a wafer.

In accordance with one aspect of the herein described embodiments, the above may be accomplished by the provision of a plasma processing apparatus including a process chamber having a wafer mounted therein such that a plasma process is performed on the wafer, and a scanning injector mounted in the process chamber such that the scanning injector supplies local plasma of a reaction gas to a local region on the wafer, the scanning injector being movable to scan the local plasma over the entire area of the wafer.

In accordance with another aspect of the herein described embodiments, there is provided a plasma processing apparatus including a process chamber having a wafer mounted therein such that a plasma process is performed on the wafer, an X-axis scanning injector mounted in the process chamber such that the X-axis scanning injector supplies a first local plasma of a reaction gas to a local region on the wafer, the X-axis scanning injector being movable in the X-axis direction to scan the first local plasma over the entire area of the wafer, and a Y-axis scanning injector mounted in the process chamber such that the Y-axis scanning injector supplies a second local plasma of a reaction gas to a local region on the wafer the Y-axis scanning injector being movable in the Y-axis direction to scan the second local plasma over the entire area of the wafer.

Preferably, the X-axis and Y-axis scanning injectors are bar-type injectors having a length equivalent to the diameter of the wafer.

Preferably, each scanning injector includes a pair of partition members arranged to define a slit therebetween such that the slit extends by a length equivalent to a diameter of the wafer with the slit being opened toward the wafer, at least one injection nozzle for injecting the reaction gas into an inner space of the slit, and a local plasma generating part for exciting the reaction gas injected from the at least one injection nozzle into plasma.

Preferably, the at least one injection nozzle includes a plurality of injection nozzles mounted at the insides of the partition members in line.

Preferably, the local plasma generating unit includes an injector radio frequency coil mounted at the partition members, and an injector radio frequency power source for applying radio frequency power to the injector radio frequency coil.

Preferably, the plasma processing apparatus further includes a scanning drive part for driving each scanning injector such that each scanning injector moves to perform the scanning operation.

Preferably, the plasma processing apparatus further includes an atmospheric gas injector mounted in the process chamber for supplying an atmospheric gas; and an atmospheric plasma generating unit mounted at the process chamber for exciting the atmospheric gas into atmospheric plasma.

Preferably, the atmospheric plasma generating unit includes a chamber radio frequency coil mounted at a side wall of the chamber, and a chamber radio frequency power source for applying radio frequency power to the chamber radio frequency coil.

Preferably, the local plasma induces deposition of a material layer on the wafer along with the atmospheric plasma.

Preferably, the local plasma induces etching of a material layer on the wafer along with the atmospheric plasma.

Preferably, the plasma processing apparatus further includes a wafer chuck for holding the wafer and a back bias power source connected to the wafer chuck for applying back bias to the rear of the wafer.

In accordance with another aspect of the herein described embodiments, there is provided a plasma processing method including mounting a wafer in a process chamber, and mounting a scanning injector in the process chamber such that the scanning injector supplies local plasma of a reaction gas to a local region on the wafer, the scanning injector being movable to scan the local plasma over the entire area of the wafer such that a plasma process is performed on the wafer.

Preferably, the local plasma induces deposition or etching of a material layer on the wafer.

Preferably, the local plasma is generated through the excitation of the reaction gas injected from injection nozzles into an inner space of a slit defined between a pair of partition members of the scanning injector such that the slit extends by a length equivalent to a diameter of the wafer with the slit being opened toward the wafer, when radio frequency power is applied to radio frequency coils mounted at the partition members.

Preferably, the plasma processing method includes supplying an atmospheric gas through an atmospheric gas injector mounted in the process chamber, and operating an atmospheric plasma generating unit mounted at the process chamber to excite the atmospheric gas into atmospheric plasma.

In accordance with a further aspect of the herein described embodiments, there is provided a plasma processing method including mounting a wafer in a process chamber of a plasma processing apparatus including the process chamber, and X-axis and Y-axis scanning injectors mounted in the process chamber for performing scanning operations on the wafer, supplying a first reaction gas to the X-axis scanning injector such that the X-axis scanning injector performs a scanning operation in the X-axis direction while the X-axis scanning injector supplies a first local plasma to a local region on the wafer (first plasma processing step), and supplying a second reaction gas to the Y-axis scanning injector such that the Y-axis scanning injector performs a scanning operation in the Y-axis direction while the Y-axis scanning injector supplies a second local plasma to a local region on the wafer (second plasma processing step).

Preferably, the first and second reaction gases are the same reaction gas or different reaction gases.

Preferably, the first and second plasma processing steps are performed to primarily deposit a material layer on the wafer, and the plasma processing method further includes supplying an etching reaction gas to the X-axis and Y-axis scanning injectors such that the X-axis and Y-axis scanning injectors sequentially perform scanning operations in the X-axis and Y-axis directions while the X-axis and Y-axis scanning injectors supply third local plasma to a local region on the wafer to etch the primarily deposited material layer, and repeatedly performing the first and second plasma processing on the etched material layer.

### BRIEF DESCRIPTION OF THE DRAWINGS

FIG. 1 is a view schematically illustrating a plasma processing apparatus according to an embodiment of the present invention;

FIG. 2 is a view schematically illustrating a scanning injector of the plasma processing apparatus according to an embodiment of the present invention;

FIG. 3 is a view schematically illustrating the plasma scanning operation of the scanning injector of the plasma processing apparatus according to an embodiment of the present invention;

FIG. 4 is a view schematically illustrating the X-axis and Y-axis scanning deposition process of the plasma processing apparatus according to an embodiment of the present invention; and

FIGS. 5 to 7 are sectional views schematically illustrating a plasma processing method according to an embodiment of the present invention.

### DESCRIPTION OF SPECIFIC EMBODIMENTS

A plasma processing apparatus is described that is capable of performing a plasma process more uniformly over the entire area of a wafer.

In an embodiment of the present invention, the plasma processing apparatus includes a scanning injector that moves to perform a scanning operation over the entire of the wafer and forms local plasma to deposit a local region on the wafer. An X-axis scanning injector is mounted in a process chamber such that the X-axis scanning injector performs a scanning operation on the wafer in the X-axis direction. A Y-axis scanning injector is also mounted in the process chamber such that the Y-axis scanning injector performs a scanning operation on the wafer in the Y-axis direction perpendicular to the X-axis direction. Through the sequential scanning operations performed by the X-axis and Y-axis scanning injectors in the X-axis and Y-axis directions, a local plasma reaction is accomplished at a local region on the wafer, and plasma reactions are sequentially accomplished by the movement of the scanning injectors from one region to another region on the wafer. In other words, scanning type plasma reactions, such as plasma deposition processes, are sequentially accomplished.

The scan injector may include a local plasma generating part, e.g., a local radio frequency (RF) coil, for generating local plasma. Consequently, the plasma is not diffused throughout the process chamber but is generated locally around the scanning injector. The generated local plasma is attracted to the wafer by back bias applied to the rear of the wafer, and therefore ions in the local plasma attracted by the back bias are deposited on the wafer. In this way, the deposition is accomplished.

The volume or size of the local plasma is much less than the inner space of the process chamber. The volume or size of the local plasma may be changed depending upon the amount of the reaction gas supplied through the injector or the size of the back bias attracting the plasma ions. Consequently, it is possible to control the volume or size of the local plasma by controlling the amount of the reaction gas and the size of the back bias. The volume or size of the local plasma is very small. As a result, the local deposition may be accomplished on the wafer in the form of a line or band. As the scanning injector moves to perform the scanning operation, the linear deposition processes are repeatedly performed, whereby the deposition of a thin layer is accomplished.

On the other hand, the X-axis and Y-axis scanning injectors may alternately perform deposition scanning operations in the X-axis and Y-axis directions. Consequently, it is possible to form a thin layer having a desired thickness by repeatedly performing the deposition scanning operations. The repetitive scanning operations in the X-axis and Y-axis directions compensate for weak points of the thin layer caused by the scanning operations performed only in one specific direction. Consequently the thickness uniformity and characteristics uniformity of the deposited thin layer are greatly improved.

Various embodiments of the present invention will now be described in detail with reference to the accompanying drawings.

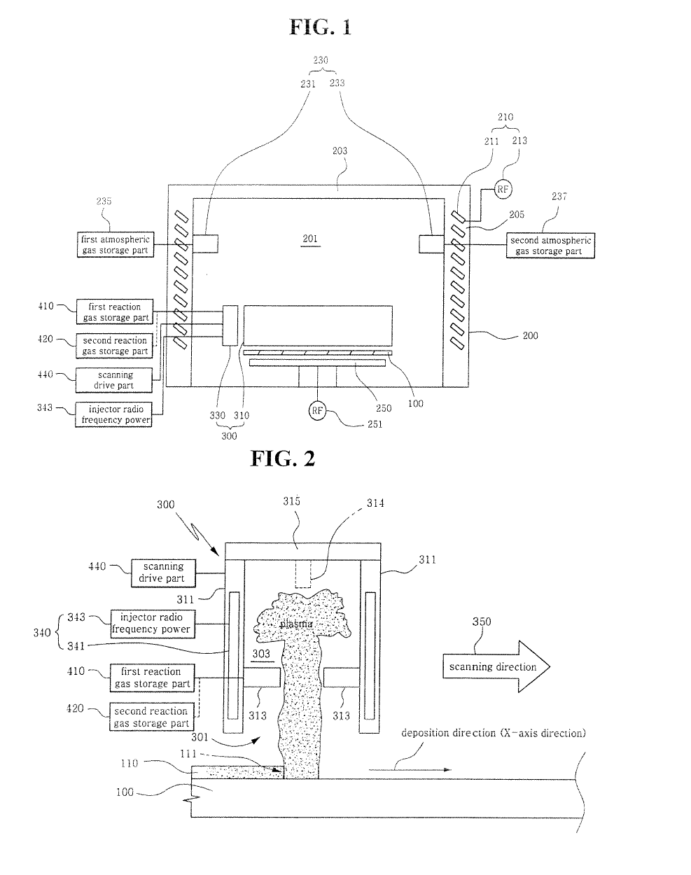

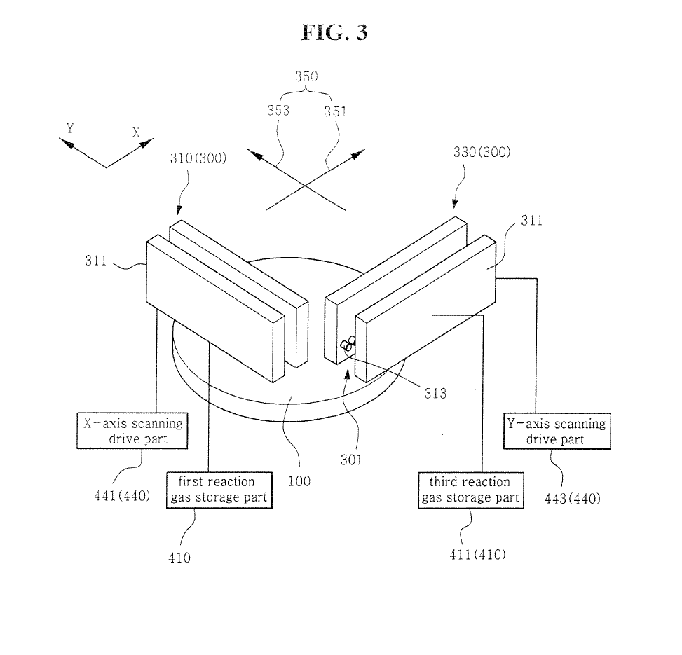

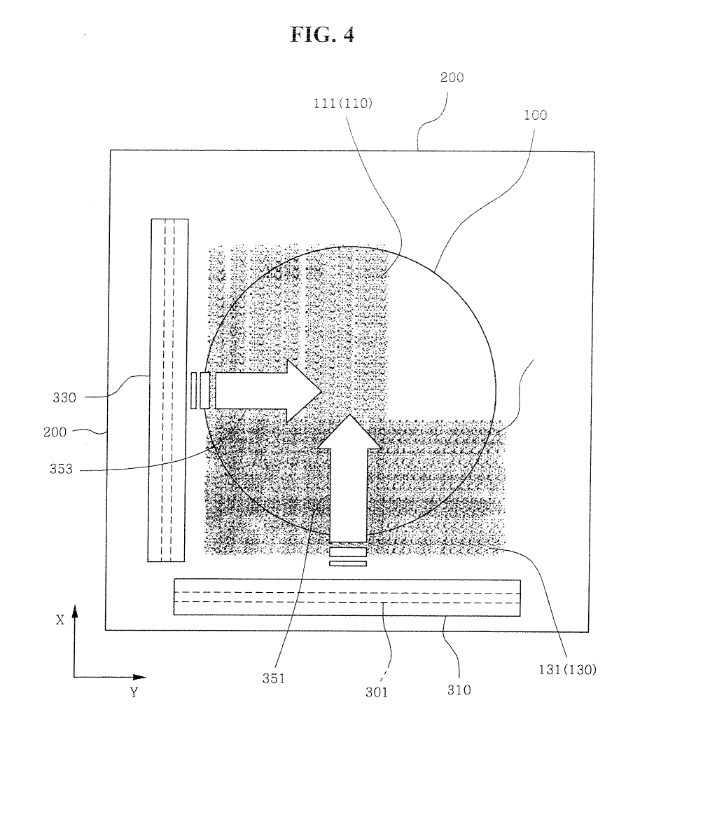

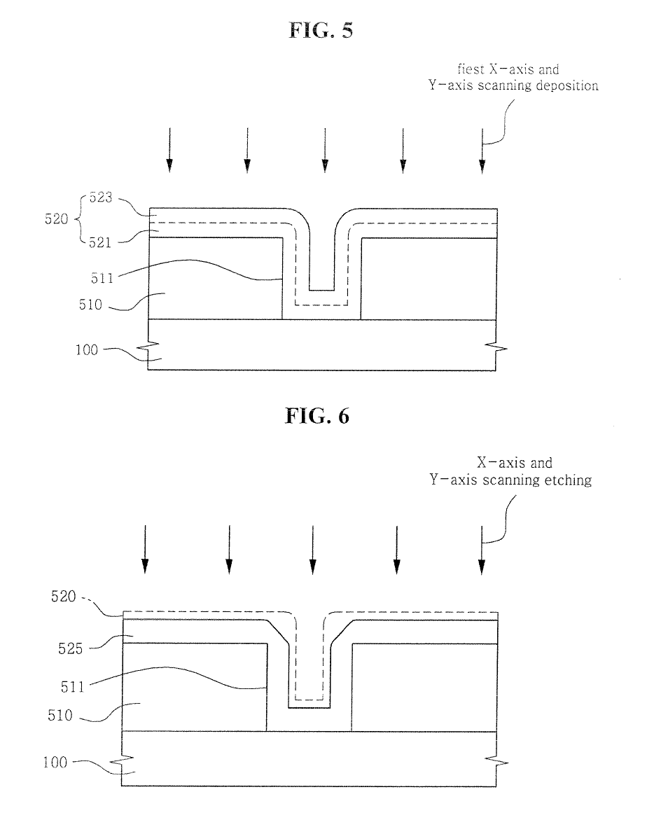

FIG. 1 is a view schematically illustrating a plasma processing apparatus according to an embodiment of the present invention FIG. 2 is a view schematically illustrating a scanning injector of the plasma processing apparatus according to an embodiment of the present invention, FIG. 3 is a view schematically illustrating the plasma scanning operation of the scanning injector of the plasma processing apparatus according to an embodiment of the present invention shown in FIG. 2, and FIG. 4 is a view schematically illustrating the X-axis and Y-axis scanning deposition process of the plasma processing apparatus according to an embodiment of the present invention.

Referring to FIG. 1, the plasma processing apparatus according to an embodiment of the present invention includes a process chamber 200 in which a process using plasma is performed on a semiconductor substrate or a wafer 100. Preferably, a depositing process using plasma is performed on the wafer 100 mounted in the process chamber 200 although an etching process using plasma may be also performed on the wafer 100 mounted in the process chamber 200. The process chamber 200 may be maintained at a pressure lower than the atmospheric pressure such that plasma can be excited in the process chamber 200. Preferably, the process chamber 200 is designed such that a high vacuum level can be maintained in the process chamber 200. In addition, a vacuum pump for forming or maintaining vacuum may be connected to the process chamber 200.

At the process chamber 200 may be mounted an atmospheric plasma generating unit 210 for generating plasma in an inner space 201 of the process chamber 200. When a plasma process is performed on the wafer 100 in the process chamber 200, it may be required that atmosphere for improving, promoting, or assisting the plasma process is created in the process chamber 200. For example, atmospheric plasma, such as an oxygen (O2) plasma or a hydrogen (H2) plasma, may be maintained in the inner space 201 of the process chamber 200.

The atmospheric plasma may be provided by using a remote plasma mode in which a carrier gas or an atmospheric gas, such as an oxygen gas or a hydrogen gas, is excited into plasma outside the process chamber 200, and the excited plasma is supplied into the process chamber 200. Preferably, however, the atmospheric plasma is excited in the process chamber 200 in order to more efficiently perform the plasma processing control. In order to generate the atmospheric plasma in the process chamber 200, the atmospheric plasma generating unit 210 is mounted at the process chamber 200 for providing an electric or magnetic field necessary to excite the supplied carrier (gas or atmospheric gas.

The atmospheric plasma generating unit 210 may include a chamber radio frequency (RF) coil 211 and a chamber radio frequency power source 213 for applying radio frequency power to the chamber radio frequency coil 211. Preferably, the chamber radio frequency coil 211 is mounted at a chamber wall 205 rather than at a chamber dome 203 disposed above the wafer 100 in order to restrain the occurrence of undesired damage caused due to the direct application of the atmospheric plasma to the wafer 100 and to accomplish more uniform atmospheric plasma density.

In order to provide atmospheric gas for atmospheric plasma into the inner space 201 of the process chamber 100, on the other hand, at least one atmospheric gas injector 230 may be mounted at the inside of the chamber wall 205. When the atmospheric plasma contains a plurality of chemical species, a plurality of atmospheric gas injectors 230 may be mounted at the inside of the chamber wall 205 to provide a plurality of atmospheric gases. Also, a plurality of atmospheric gas injectors 230 may be mounted at the inside of the chamber wall 205 to provide more uniform atmospheric plasma density distribution in the inner space 201 of the process chamber 200.

For example, a first atmospheric gas injector 231 for supplying an oxygen gas and a second atmospheric gas injector 231 for supplying a hydrogen gas may be independently mounted at the inside of the chamber wall 205. Also, a first atmospheric gas storage part 235 for supplying an oxygen gas, for example an oxygen storage tank, may be connected to the first atmospheric gas injector 231. Similarly, a second atmospheric gas storage part 237 for supplying a hydrogen gas, for example a hydrogen storage tank, may be connected to the second atmospheric gas injector 233.

The wafer 100 introduced into the process chamber 200 is mounted on a wafer chuck 250 disposed at the bottom of the process chamber 200. The wafer chuck 250 may be an electrostatic chuck (ESC). To the rear of the wafer chuck 250 may be applied back bias for accelerating or attracting ions in the plasma onto the wafer 100 during the plasma process. A back bias radio frequency power source 251 for applying the back bias to the rear of the wafer 100 may be connected to the wafer chuck 250.

In order to perform the plasma process on the wafer 100 mounted on the wafer chuck 250, a scanning injector 300 is mounted in the process chamber 200 such that the scanning injector 300 can move horizontally over the wafer 100. A single scanning injector 300 may perform a plasma scanning operation in alternating scanning directions. Preferably, however, the scanning injector 300 includes a pair made of a X-axis scanning injector 310 and a Y-axis scanning injector 330 that extend in perpendicular directions. The scanning injector 300 performs the plasma process while scanning across the wafer 100. Consequently, it is more efficient to perform the plasma process over the entire region of the wafer by one scanning. To this end, the scanning injector 300 may be constructed as a bar-type injector having a length equivalent to the diameter of the wafer 100.

Referring to FIGS. 2 and 3 together with FIG. 1, the scanning injector 300 may be constructed as a bar-type injector having a length equivalent to the diameter of the wafer 100. As shown in FIG. 2, the scanning injector 300 may include two injector partition members 311 arranged opposite to each other such that a slit 301 for supplying local plasma is defined between the injector partition members 311. As shown in FIG. 3, each partition member 311 may be formed in the shape of a board extending such that the each partition member 311 has a length equivalent to the diameter of the wafer 100. The partition members 311 are connected with each other via a connection member 315, such as a connection shaft, such that the slit 301 is formed above the wafer 100.

A reaction gas for plasma reaction is provided in an inner space 303 of the slit 301. To this end, injection nozzles 313 for injecting the reaction gas may be mounted at the insides of the partition members 311 such that the injection nozzles 313 extend toward the opposite insides of the partition members 311, respectively. As shown in FIG. 2, the injection nozzles 313 may be opposite to each other. Also, a plurality of injection nozzles 313 may be arranged in the longitudinal direction of the partition members 311. According to circumstances, a plurality of injection nozzles 314 may be mounted at the connection member 315 such that the injection nozzles 314 are arranged in the longitudinal direction of the connection member 315. Nevertheless, it is advantageous to mount a plurality of injection nozzles 313 at the insides of the partition members 311 such that the injection nozzles 313 are arranged in the longitudinal direction of the partition members 311, as shown in FIG. 3 because the density distribution of the local plasma can be more uniformly maintained.

In order to supply a reaction gas into the inner space 303 of the slit 301 through the injection nozzles 313, a reaction gas storage part 410 may be connected to the injection nozzles 313 via connection pipes. In this case, the connection pipes may include flexible connection pipes that allow proper scanning operation of the scanning injector 300. The reaction gas storage part 410 may be a container for storing silane (SiH4) as a reaction gas for deposition or nitrogen trifluoride (NF3) as a reaction gas for etching. When deposition-etching-deposition processes are repeatedly performed as in a HDP oxide layer depositing process it may be required to repeatedly provide a reaction gas for deposition and a reaction gas for etching. In this case, a first reaction gas storage part 410 for storing a reaction gas for deposition and a second reaction gas storage part 420 for storing a reaction gas for etching are connected to the injection nozzles 313 such that the first reaction gas storage part 410 and the second reaction gas storage part 420 can be alternately connected to the injection nozzles 313 by the switching operation.

The reaction gas storage part 410 may be connected to both the X-axis scanning injector 310 and the Y-axis scanning injector 330 such that the same reaction gas can be supplied to the X-axis scanning injector 310 and the Y-axis scanning injector 330. Preferably, however, as shown in FIG. 3, the first reaction gas storage part 410 is connected to the X-axis scanning injector 310, and a third reaction gas storage part 411 is connected to the Y-axis scanning injector 330. This construction may be suitably applied when reactions are sequentially performed including two or more chemical species, for example when atomic layered deposition (ALD) is performed.

In order to excite the reaction gas supplied into the inner space 303 of the slit 301 through the injection nozzles 313 into plasma, as shown in FIG. 2, local plasma generating units 340 may be independently mounted at the respective injectors 300. Each local plasma generating unit 340 may include an injector radio frequency coil 341 to which radio frequency power for the plasma excitation is applied and an injector radio frequency power source 343 for applying radio frequency power to the injector radio frequency coil 341. In this case, the injector radio frequency coils 341 may be mounted in the respective partition members 311.

The reaction gas supplied into the inner space 303 of the slit 301 through the injection nozzles 313 are excited into plasma by the radio frequency power applied to the injector radio frequency coils 341. The excited plasma is restricted in the inner space 303 of the slit 301. Consequently, the excited plasma may be local plasma existing only in a local region. The excited local plasma reaches the wafer 100 through the slit 301 and induces local plasma reaction the restricted local region on the wafer 100. At this time, ions in the local plasma are attracted to the wafer 100 by the back bias applied to the rear of the wafer 100. As a result, plasma enhanced-chemical vapor deposition (PE-CVD) is locally performed on the wafer 100. Also, the etching process may be oriented or reinforced by the actions of ions accelerated by the back bias during the plasma etching.

In the plasma deposition to deposit a material layer 110, for example an oxide layer, on the wafer 100, as shown in FIG. 2, the local deposition is induced with respect to restricted local deposition regions 111 on the wafer 100. At this time, the width of the local deposition regions 111 may be changed depending upon the slit structure of the injector 300, i.e., the width of the slit 301, the amount of supplied reaction gas, or the radio frequency power applied to the injector radio frequency coils 341. Consequently, it is possible to adjust the width of the local deposition regions 111 by controlling the above-specified parameters. As a result, it is possible to accomplish line contact deposition in which lines having a length equivalent to the length of the injector 300 are scanned due to the narrow width of the local deposition regions 111, and therefore, it is possible to accomplish more uniform deposition of the material layer 110.

As the deposition is performed locally with respect to the linear region, it is required to perform the scanning operation of the scanning injector 300 such that the material layer 110 can be deposited over the entire wafer 100. As shown in FIG. 3, the scanning operation of the scanning injector 300 may be performed in one scanning direction 350, e.g., an X-axis direction 351, before another scanning direction 350, e.g., a Y-axis direction 353, in consideration of the uniformity of the material layer 110 to be deposited. The alternating scanning operations of the scanning injector 300 in the X-axis and Y-axis direction may be performed by one scanning injector 300. In this case, it is required the position of the scanning injector 300 to be changed. More preferably, however, the alternating scanning operations of the scanning injector 300 in the X-axis and Y-axis direction are performed by the X-axis scanning injector 310 and the Y-axis scanning injector 330 in consideration of deposition efficiency.

In order to perform the scanning operation of the scanning injector 300, a scanning drive part 440, including a drive motor, may be connected to the scanning injector 300 via a connection drive shaft. The scanning drive part 440 provides a drive force necessary for the scanning injector 300 to performing a scanning operation on the wafer 100. For example, as shown in FIG. 3, an X-axis scanning drive part 441 drives the X-axis scanning injector 310 such that the X-axis scanning injector 310 scans in the X-axis direction 351, and a Y-axis scanning drive part 443 drives the Y-axis scanning injector 330 such that the Y-axis scanning injector 330 scans in the Y-axis direction 353. In this way, the local plasma reaction is performed over the entire region of the wafer 100 by the X-axis and Y-axis scanning operations, whereby the uniformity of the plasma process is greatly improved.

Referring to FIG. 4, the plasma process may be performed including an X-axis scanning process performed in the X-axis direction 351 and a Y-axis scanning performed process in the Y-axis direction 353. Also, the X-axis and Y-axis scanning processes may be repeatedly performed such that the plasma process is advanced to a desired degree. For example, when local plasma is generated to be scanned on the wafer 100 while moving the X-axis scanning injector 310 on the wafer 100 in the X-axis direction 351, local deposition regions 111 are deposited on the wafer 100 while the local deposition regions 111 are in line contact with each other. A first material layer 110 is deposited on the wafer 100 by the plasma scanning deposition in the X-axis direction 351.

At this time, the thickness uniformity or film quality characteristics uniformity of the first material layer 110 may change due to one-directional scanning. In order to compensate for it, local plasma is generated to be scanned on the wafer 100 while moving the Y-axis scanning injector 330 on the wafer 100 in the Y-axis direction 353. As a result, local deposition regions 131, perpendicular to the local deposition regions 111, are deposited on first material layer 110 while the local deposition regions 131 are in line contact with each other. Consequently, a second material layer 130 is deposited on the material layer 110. These X-axis and Y-axis scanning processes are performed in perpendicular directions, and therefore the weakness caused at the respective deposited material layers 110 and 130 are compensated for. As a result, the resultant material layers 110 and 130 have more uniform thickness and film quality characteristics.

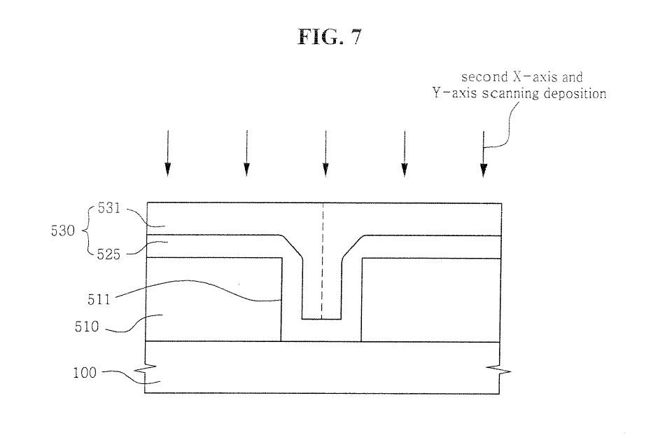

FIGS. 5 to 7 are sectional views schematically illustrating a plasma processing method according to an embodiment of the present invention.

Referring to FIG. 5, a wafer 100 having a lower layer 510 disposed on the upper surface thereof is mounted on a wafer chuck 250 of a plasma processing apparatus as shown in FIG. 1. The lower layer 510 may be an insulation layer patterned to have a concave part, such as a contact hole or a trench 511. Furthermore, the lower layer 510 may be a semiconductor substrate or a wafer 100 having a trench 511 for a device isolation layer.

Subsequently, high vacuum necessary for a plasma process, e.g., a deposition process, is formed in the inner space 201 of the process chamber 200. After that, the X-axis and Y-axis scanning injectors 310 and 320 are alternately moved to deposit a first deposition layer 520 in the trench 511. When the first deposition layer 520 is deposited including a silicon oxide layer for the device isolation layer, a silane gas is supplied to the scanning injectors 300, and an oxygen gas as an atmospheric gas, is supplied through the first atmospheric gas injector 231. In order to excite the oxygen gas into plasma, the atmospheric plasma generating part 210 is turned on, and radio frequency power is applied to the chamber radio frequency coil 211. As a result, an oxygen plasma atmosphere is created in the inner space 201 of the process chamber 200.

A silicon source gas, e.g., a silane gas, is supplied to the X-axis scanning injector 310, and radio frequency power is applied to the injector radio frequency coil 341 (see FIG. 2) of the X-axis scanning injector 310. As a result, local plasma is generated in the inner space 303 (see FIG. 2) of the slit 301. The local plasma is generated by the width of the split 301 and reaches the lower layer 510 on the wafer 100, where the oxygen plasma atmosphere and the silane gas plasma react with each other such that a deposition process is performed. At this time, back bias may be applied to reinforce the deposition process, whereby the gap filling characteristics of the trench 511 is improved.

A first sub-layer 521 of the first deposition layer 520 is deposited by the plasma scanning operation of the X-axis scanning injector 310 in the X-axis direction 351 (see FIG. 3). After that, a second sub-layer 523 is deposited on the first sub-layer 521 by the plasma scanning operation of the Y-axis scanning injector 330 (see FIG. 1) in the Y-axis direction 353 (see FIG. 3).

In this way, the first deposition layer 520 is formed by the first X-axis and Y-axis depositions. At this time, a process for etching the first deposition layer 520 may be performed in order to further improve the gap-filling characteristics at the entrance of the trench 511.

Referring to FIG. 6, etching reaction gas plasma is introduced onto the first deposition layer 520 to perform the etching process. For example, a reaction gas from the second reaction gas storage part 420 (see FIG. 1) is supplied to the X-axis scanning injector 310. As a result, a nitrogen trifluoride (NF3) gas, as an etching reaction gas, is supplied to the scanning injectors 300. An atmospheric gas. e.g., a hydrogen gas, is supplied through the second atmospheric gas injector 233.

Hydrogen plasma excited from the hydrogen gas and local plasma of the nitrogen trifluoride gas react with each other on the first deposition layer 520 to etch the first deposition layer 520. This etching process may be performed by the X-axis and Y-axis plasma scanning operations. At this time, back bias may be applied to reinforce the etching characteristics in the perpendicular direction, thereby accomplishing anisotropic etching. The etching degree or the etching rate distribution of the first deposition layer 520 may be made uniform by the X-axis and Y-axis plasma scanning operations. An etched first deposition layer 525 is formed through the etching of the first deposition layer 520. Consequently, it is possible to accomplish dense film quality of the deposition layers including the etched first deposition layer 525 and to improve the gap-filling characteristics of the trench 511.

The edge of the first deposition layer 520 at the entrance of the trench 511 may be excessively etched to decrease the aspect ratio at the entrance of the trench 511 through the X-axis and Y-axis plasma scanning etching operations. In addition, the profile at the entrance of the trench 511 may be changed such that the profile becomes gentler. As a result, when a second deposition layer is deposited on the etched first deposition layer 525, the gap-filling characteristics of the trench 511 are improved.

Referring to FIG. 7, second X-axis and Y-axis scanning deposition operations are performed on the etched first deposition layer 525 to deposit a second deposition layer 531 on the etched first deposition layer 525. Through the above-described deposition processes, it is possible to finally form a desired deposition layer 530. At this time, the X-axis and Y-axis plasma scanning deposition-etching-deposition processes may be repeatedly performed to increase the thickness uniformity and film quality characteristics uniformity of the deposition layer 530.

In the above-described embodiments of the present invention, the plasma process was used to deposit the silicon oxide layer; however, the plasma processing apparatus according to the various embodiments of the present invention may be suitably used in various processes using plasma, including an etching process, in addition to the deposition process.

As apparent from the above description in various embodiments the present invention provides a plasma processing apparatus having a scanning injector that is capable of performing a plasma process uniformly over the entire area of a wafer. The scanning injector performs a scanning operation such that a deposition profile is uniformly formed over the entire area of the wafer. Consequently, it is possible uniformalize the thickness, characteristics and physical properties of a deposited thin layer.

Furthermore, local deposition is possible at a local region, whereby the uniformly of the thin layer is greatly improved. The scanning injectors, which are arranged such that the scanning injectors can perform the scanning operations in perpendicular directions, are alternately moved to perform the deposition process, thereby greatly increasing the uniformity of the thin layer. Also, it is possible to individually control the plasma generation degree for each scanning injector. As a result, when the deposition-etching-deposition processes are performed in the same manner as the HDP deposition process, it is possible to more efficiently control ion sputtering rate. Consequently it is possible to improve the gap-filling characteristics of the trench or contact hole.

Although several embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A plasma processing apparatus comprising:
a process chamber having a mount for a wafer such that a plasma process is performed on a wafer when mounted on the mount in the process chamber; and
a scanning injector mounted in the process chamber such that the scanning injector supplies a local plasma of a reaction gas to a local region of the mount, the scanning injector being movable to scan the local plasma over an entire area of the mount corresponding to a mounted wafer.

2. The plasma processing apparatus according to claim 1, wherein the scanning injector includes
a pair of partition members arranged to define a slit therebetween such that the slit extends by a length equivalent to a diameter of the wafer with the slit being opened toward the wafer,
at least one injection nozzle for injecting the reaction gas into an inner space of the slit, and
a local plasma generating part for exciting the reaction gas injected from the at least one injection nozzle into plasma.

3. The plasma processing apparatus according to claim 1, further comprising:
a scanning drive part for driving the scanning injector such that the scanning injector moves to perform the scanning operation.

4. The plasma processing apparatus according to claim 1, further comprising:
an atmospheric gas injector mounted in the process chamber for supplying an atmospheric gas; and
an atmospheric plasma generating unit mounted at the process chamber for exciting the atmospheric gas into atmospheric plasma.

5. The plasma processing apparatus according to claim 4, wherein the local plasma induces deposition of a material layer on a wafer mounted to the mount along with the atmospheric plasma.

6. The plasma processing apparatus according to claim 4, wherein the local plasma induces etching of a material layer on a wafer mounted to the mount along with the atmospheric plasma.

7. The plasma processing apparatus according to claim 1, further comprising:
a wafer chuck for holding a wafer; and
a back bias power source connected to the wafer chuck for applying back bias to the rear of on a wafer mounted to the wafer chuck.

8. A plasma processing apparatus comprising:
a process chamber having a mount for a wafer therein such that a plasma process is performed on a wafer mounted to the mount;
an X-axis scanning injector mounted in the process chamber such that the X-axis scanning injector supplies a first local plasma of a reaction gas to a local region of the mount corresponding to a mounted wafer, the X-axis scanning injector being movable in the X-axis direction to scan the first local plasma over an entire area of a mounted wafer; and
a Y-axis scanning injector mounted in the process chamber such that the Y-axis scanning injector supplies a second local plasma of a reaction gas to a local region of the mount corresponding to a mounted wafer, the Y-axis scanning injector being movable in the Y-axis direction to scan the second local plasma over the entire area of a mounted wafer.

9. The plasma processing apparatus according to claim 8, wherein the X-axis and Y-axis scanning injectors are bar-type injectors having a length equivalent to the diameter of a mounted wafer.

10. The plasma processing apparatus according to claim 8, wherein each scanning injector includes
a pair of partition members arranged to define a slit therebetween such that the slit extends by a length equivalent to a diameter of a mounted water with the slit being opened toward the mount,
at least one injection nozzle for injecting the reaction gas into an inner space of the slit, and
a local plasma generating part for exciting the reaction gas injected from the at least one injection nozzle into plasma.

11. The plasma processing apparatus according to claim 10, wherein the at least one injection nozzle includes a plurality of injection nozzles mounted at the insides of the partition members in line.

12. The plasma processing apparatus according to claim 10, wherein the local plasma generating unit includes
an injector radio frequency coil mounted at the partition members, and
an injector radio frequency power source for applying radio frequency power to the injector radio frequency coil.

13. The plasma processing apparatus according to claim 8, further comprising:
a scanning drive part for driving each scanning injector such that each scanning injector moves to perform the scanning operation.

14. The plasma processing apparatus according to claim 8, further comprising:
an atmospheric gas injector mounted in the process chamber for supplying an atmospheric gas; and
an atmospheric plasma generating unit mounted at the process chamber for exciting the atmospheric gas into atmospheric plasma.

15. The plasma processing apparatus according to claim 14, wherein the atmospheric plasma generating unit includes
a chamber radio frequency coil mounted at a side wall of the chamber, and
a chamber radio frequency power source for applying radio frequency power to the chamber radio frequency coil.

16. The plasma processing apparatus according to claim 14, wherein the local plasma induces deposition of a material layer on a wafer mounted to the mount along with the atmospheric plasma.

17. The plasma processing apparatus according to claim 14, wherein the local plasma induces etching of a material layer on a wafer mounted to the mount along with the atmospheric plasma.

18. The plasma processing apparatus according to claim 8, further comprising:
a wafer chuck for holding a wafer; and
a back bias power source connected to the wafer chuck for applying back bias to the rear of a wafer mounted to the wafer chuck.

19. A plasma processing method comprising
mounting a wafer in a process chamber; and
mounting a scanning injector in the process chamber such that the scanning injector supplies local plasma of a reaction gas to a local region on the wafer, the scanning injector being movable to scan the local plasma over the entire area of the wafer such that a plasma process is performed on the wafer.

20. The plasma processing method according to claim 19, wherein the local plasma induces deposition or etching of a material layer on the wafer.

21. The plasma processing method according to claim 19, wherein the local plasma is generated through the excitation of the reaction gas injected from injection nozzles into an inner space of a slit defined between a pair of partition members of the scanning injector such that the slit extends by a length equivalent to a diameter of the wafer with the slit being opened toward the wafer, when radio frequency power is applied to radio frequency coils mounted at the partition members.

22. The plasma processing method according to claim 19, further comprising:
supplying an atmospheric gas through an atmospheric gas injector mounted in the process chamber; and
operating an atmospheric plasma generating unit mounted at the process chamber to excite the atmospheric gas into atmospheric plasma.

23. A plasma processing method comprising:
mounting a wafer in a process chamber of a plasma processing apparatus including the process chamber, and X-axis and Y-axis scanning injectors mounted in the process chamber for performing scanning operations on the wafer:
supplying a first reaction gas to the X-axis scanning injector such that the X-axis scanning injector performs a scanning operation in the X-axis direction while the X-axis scanning injector supplies a first local plasma to a local region on the wafer (first plasma processing); and
supplying a second reaction gas to the Y-axis scanning injector such that the Y-axis scanning injector performs a scanning operation in the Y-axis direction while the Y-axis scanning injector supplies a second local plasma to a local region on the wafer (second plasma processing).

24. The plasma processing method according to claim 23, wherein the first and second reaction gases are the same reaction gas or different reaction gases.

25. The plasma processing method according to claim 24, wherein
the first and second plasma processing are performed to primarily deposit a material layer on the wafer, and
the plasma processing method further comprises:
supplying an etching reaction gas to the X-axis and Y-axis scanning injectors such that the X-axis and Y-axis scanning injectors sequentially perform scanning operations in the X-axis and Y-axis directions while the X-axis and Y-axis scanning injectors supply a third local plasma to a local region on the wafer to etch the primarily deposited material layer; and
repeatedly performing the first and second plasma processing on the etched material layer.
